(19) United States
(12) Patent Application Publication
(10) Pub. No.: US 2007/0037346 A1
(43) Pub. Date: Feb. 15, 2007

(54) Rapid thermal annealing of targeted thin film layers

(76) Inventor: Robert W. Grant, Camden, ME (US)

Correspondence Address: GREENBERG TRAURIG, LLP, ONE INTERNATIONAL PLACE, 20th FL, ATTN: PATENT ADMINISTRATOR, BOSTON, MA, 02110, US

(21) Appl. No.: 11/479,716

(22) Filed: Jun. 30, 2006

Related U.S. Application Data
(63) Continuation-in-part of application No. 11/358,343, filed on Feb. 21, 2006.
(60) Provisional application No. 60/696,049, filed on Jul. 1, 2005.
(60) Provisional application No. 60/655,252, filed on Feb. 22, 2005.

(51) Int. Cl. H01L 21/8242; H01L 21/4763

(52) U.S. Cl. 438/243; 438/247; 438/625; 257/E23.109; 257/E21.294

(57) ABSTRACT

A method for rapid thermal annealing of thin film layers is provided. The method directs a series of pulses or flashes of heat energy toward a targeted layer on a substrate. Each pulse may be at a first temperature range sufficient to anneal the targeted layer, but has a duration that is less than that necessary to render the targeted layer substantially annealed. Moreover, in succession, the series of pulses can incrementally raise the targeted layer to a temperature sufficient for annealing, while minimizing exposure of the remaining layers to the pulses of heat energy. A reactor for implementing the rapid thermal annealing process is also provided.

### RELATED US APPLICATION(S)

The present application claims priority to U.S. Provisional Patent Application Ser. No. 60/696,049, filed Jun. 30, 2005, and is a continuation-in-part of U.S. patent application Ser. No. 11/358,343, filed Feb. 21, 2006, both of which are hereby incorporated herein by reference.

### TECHNICAL FIELD

The present invention relates to methods of annealing targeted thin film layers on a substrate, and more particularly, to a rapid thermal annealing process while maintaining a gradient of temperature across different layers.

### BACKGROUND ART

New techniques in patterning and deposition have led the way in fulfilling Moore's Law (the historical increase in processor speed), as well as the trend toward lower cost via smaller feature sizes and denser circuitry. Over the history of Large Scale Integrated (LSI) circuits, transistor density has increased dramatically to the extent that as the scale of construction has been halved, the density of transistors has increased by four. In addition, as the density increases, power consumption and electrical current requirements have also increased. In order to isolate transistors from voltage fluctuations resulting from the increased current and lower voltage, measures have been taken, for instance, large (decoupling) capacitors have been designed to isolate the LSI from power supply fluctuations. However, many of the required capacitors (currently planar) have grown in size to a point that they can no longer fit onto the IC chip.

Today, it is common for these capacitors to be mounted off the chip and onto the printed circuit board. The farther away the decoupling capacitor is mounted from the LSI chip, however, the worse the overall performance of the connecting “wires.” If the decoupling capacitors could be mounted on the chip or even on the intermediate chip mount at low cost, then printed circuit board space and overall cost could be greatly reduced.

Historically, capacitors have been formed on substrates, or more specifically, Silicon wafers, by depositing and patterning thin films of dielectric material and covering the dielectric material with a thin metal film as an electrode. As integrated circuits continue to be made smaller and smaller, the size of the capacitors also need to shrink. However, as sizes shrink to the micron or sub-micron size, the needed capacitance sometimes cannot be achieved within the new small area.

To address this, one approach has been to increase the dielectric property of the insulator. This can been achieved with materials, such as oxides of Hafnium or Tantalum, etc. In particular, if multiple metal oxides, such as high-k dielectrics and metal electrodes can be deposited conformally onto a Silicon wafer, then the space requirements of capacitor structures can be easily reduced, saving hundreds of millions of dollars in production costs. For example, if a Barium Strontium Titanate (BST) dielectric can be effectively used instead of the now common SiO₂ dielectric, a 40 times capacitor area reduction can be achieved. However, although the relative dielectric strength of these materials can help reduce the feature size of the capacitor, such can limit, for instance, the compatibility of the new materials.

Currently, metal oxide deposited as barrier layers (e.g., oxides of Ru, Pd, Ti, Ta, etc.), dielectrics and perovskites (e.g., oxides of Al, Ta, Hf, SBT, BLT, BST, PZT etc.), and/or conductors (e.g., Pt, Ru, Ir, Cu etc.) onto a substrate in the fabrication of an integrated circuit are typically annealed after their deposition in the presence of Oxygen or Nitrogen by the use of a furnace or conventional rapid thermal processing. These approaches, however, expose all of the layers simultaneously to a uniform temperature over a period of time, for example, from about 400° C. to about 1200° C. for about sixty seconds to a few hours. When targeting, for instance, only an upper layer for annealing, exposure of the underlying layers, along with other FETs and interconnects, to similar heating conditions can damage the underlying layers and compromise the performance of the underlying layers.

To address this, a process employing low thermal “budget”, such as that disclosed in U.S. Pat. No. 6,815,223 (the '223 patent), has been employed to minimize exposure of the underlying layers to conditions necessary to activate or complete a chemical or crystalline reaction on, for instance, a targeted upper layer. Thermal “budgets”, as defined by the '223 patent, is the product of the elevated processing temperature (expressed in ° C.) multiplied by the time (at the elevated temperature in seconds). The resulting thermal “budget” is expressed as “degrees C.-sec”. In the '223 patent, the practical lower limit of the thermal budget was stated to be less than 50,000 degrees C./sec. For instance, in the case of SBTN, the processing conditions were at about 750° C. for 60 seconds or so, making the thermal budget about (750×60) to 45,000° C.-seconds. Although the entire wafer was exposed to these conditions, such was the estimate necessary to complete the chemical reactions required to crystallize the SBT family of materials into the Perovskite phase, while protecting the lower layers of the IC substrate from accumulated alteration due to rapid thermal treatment and/or furnace operation.

As IC dimensional design shrink, exposure of underlying layers to conditions necessary to complete the annealing process in the top layer, even at a low thermal budget, can compromise the integrity of the underlying layers. It is now understood that underlying IC layers need to be subject to much lower thermal conditions in order to not be damaged. In particular, shallow junctions, interconnect metal contacts etc. need to be protected from prolonged exposure to temperature and time. A way was needed to permit completion of the oxidation or chemical reactions in the metal oxide or barrier or electrode layers without exposing the underlying layers to too much temperature and time.

Certain methods have been employed to date whereby trace elements, such as Niobium, are added to metal oxides (e.g. SBT) to reduce the crystallization temperature without altering other important qualities. Other methods have employed working under atmospheric conditions within the various conventional furnace treatment or rapid thermal processing. In many of these cases, the entire substrate needed to be held carefully at a particular temperature, often with specified variations of ±2° C., after a ramp to a temperature set point of about 650° C. or 700° C. for several seconds (rapid thermal processing) or minutes (furnace treatment). Moreover, after patterning of the metal oxide, top electrode and/or barrier layer, a recovery anneal must often be employed in order to repair damage to the metal oxides by, for instance, Chlorine or Fluorine etch chemistry. Other types of etching, such as electron beam or ion milling, can also cause damage and require prolonged exposure of the entire substrate to the heating condition.

Other approaches, such as excimer lasers, flash lamps, and microwave pulse generators have been used to heat and anneal the upper thin film or layer on the substrate. In laser annealing, short-wavelength monochromatic radiation produced by the laser can be absorbed at very shallow depths. Moreover, the short duration, high-power laser pulse (e.g., a 10 nanosecond pulse delivering about 0.4 J/cm² to the device side surface) typically used for this process can heat a small localized area of the surface of the substrate to melting or near-melting temperatures very rapidly, in significantly less than the time required for thermal conduction in the substrate. Accordingly, the bulk regions of the substrate tend to remain cold, and can therefore act as a heat sink for the heated surface region, causing the surface region to cool very quickly. However, because the bulk regions of the substrate remain cold when the localized surface area of the substrate is heated to the annealing temperature, extreme thermal gradients are produced, resulting in large mechanical strains which cause the crystal planes within the underlying layers of substrate to slip, thereby damaging or breaking their crystal lattice. In this regard, a very small spatial movement can completely destroy the crystal lattice. Thermal gradients may also cause other damage, such as warpage or defect generation. Even in the absence of slippage, a non-uniform temperature distribution across the substrate may cause non-uniform performance-related characteristics, resulting in either inadequate performance of the particular capacitor, or undesirable performance differences from capacitor to capacitor. In addition, the large amount of energy delivered by the laser or lasers to the substrate is non-uniformly absorbed thereon, resulting in deleterious heating effects in regions of the substrate where annealing is not desired, and may also produce further large temperature gradients causing additional damage to the silicon lattice.

Accordingly, it would be desirable to provide a method for annealing targeted layers on a substrate, such that the targeted layer may be heated to a desired temperature, while minimizing exposure of underlying layers to such desired temperature to prevent degradation of those underlying layers.

### SUMMARY OF THE INVENTION

The present invention provides, in one embodiment, a rapid thermal annealing method for use in connection with the fabrication of an integrated circuit capacitor.

In accordance with an embodiment, the method includes providing, on a substrate, a plurality of thin film layers. The layers, in one embodiment, may include metals or metal oxides, such as SBT, BST, BLT, PZT, or other multiple or single metal materials. Next, a first temperature range sufficient to anneal a targeted layer on the substrate may be generated. The first temperature range may be from about 400° C. to about 1000° C. Once generated, the targeted layer may be exposed to the first temperature range, for a predetermined time period less than that necessary to render the targeted layer substantially annealed, so as to minimize exposure of the remaining layers to the first temperature range. Exposure may be for a few milliseconds to a pulse or a flash of heat energy. By minimizing exposure of the remaining layers to the first temperature range damages to the remaining layers can be avoided. Thereafter, the targeted layer may be cooled to a second temperature range below that of the first temperature range. For instance, the second temperature range may be about half of the first temperature range. Subsequently, the substrate may be re-exposed to the first temperature range, for the predetermined time period, to reheat the targeted layer toward the first temperature range. The re-exposure permits additional energy to be absorbed into the targeted layer to further increase its thermal profile towards the temperature that permit subsequent annealing of the targeted layer.

In accordance with another embodiment of the present invention, a method is provided for annealing a targeted layer on a substrate. The method includes initially pre-heating a substrate having a plurality of overlapping thin film layers to an intermediate temperature. Next, a rapid pulse of heat energy at a first temperature range higher than the intermediate temperature and sufficient to anneal a targeted layer may be emitted toward a targeted layer. The pulse of heat energy, in an embodiment, is only for a predetermined time period less than that necessary to render the targeted layer substantially annealed. As such, exposure of the remaining layers to the first temperature range may be minimized. The targeted layer may then be cooled to a second temperature range below the first temperature range but higher than the intermediate temperature. Thereafter, another rapid pulse of heat energy at the first temperature range may be directed toward the targeted layer for the duration of the predetermined time period to raise the temperature of targeted layer from the second temperature range towards the first temperature range. Since the pulse is of a short duration, exposure of the remaining layers to the first temperature range is again minimized.

The present invention further provides a reactor for performing rapid thermal annealing. The reactor includes, in one embodiment, a platform upon which a substrate having a plurality of layers to be annealed can be positioned. The reactor also includes a heat source for emitting toward a targeted layer on the substrate a series of rapid pulses of heat energy. Each individual pulse may be at a first temperature range and may last for a predetermined time period less than that necessary to render the targeted layer substantially annealed. Moreover, in succession, the series of pulses can incrementally raise the targeted layer to a temperature sufficient for annealing, while minimizing exposure of the remaining layers to the pulses of heat energy. The reactor further includes a sensor to measure, upon cooling of the targeted layer between pulses, a second temperature range of the targeted layer. This second temperature range may be below the first temperature range to provide a feedback signal used in the initiation of the next successive pulse of heat energy. The reactor may also include a second heat source for pre-heating the substrate and plurality of layers to an intermediate temperature prior to emission of heat energy from the heat source, a reflective material to substantially uniformly direct heat energy from the heat source toward the targeted layer, and a heat sink positioned about the substrate to minimize conduction of heat away from the targeted layer.

### BRIEF DESCRIPTION OF DRAWINGS

FIG. 1 illustrates a system for Chemical Fluid Deposition using supercritical conditions in accordance with an embodiment of the present invention.

FIG. 2 illustrates a capacitor manufactured in accordance with a method of the present invention

FIG. 3 illustrates a reactor for use in connection with a rapid thermal annealing process of the present invention

FIG. 4 shows a graph illustrating the heating cycles implemented by a method of the present invention.

FIG. 5 illustrates a three dimensional capacitor array manufactured in accordance with one embodiment of the present invention.

FIG. 6 is a graph illustrating the range along which the capacitance density may be increased in connection with a capacitor of the present invention.

### DESCRIPTION OF SPECIFIC EMBODIMENTS

The present invention provides, in one embodiment, a rapid thermal annealing (RTA) method for use in connection with the fabrication of a capacitor whereby an upper thin film or layer (i.e., targeted layer) of an integrated circuit may be heated to a desired temperature range, while exposure of the underlying layers to such a temperature range may be minimized, so as to avoid damage to the underlying layers.

In accordance with one embodiment of the present invention, the RTA method involves the use of, for example, impulse, flash-assist or laser anneal, subsequent to the deposition of a metal or metal oxide as barrier layers (e.g., oxides of Ru, Pd, Ti, Ta, etc.), dielectrics and perovskites (e.g., oxides of Al, Ta, Hf, SBT, BLT, BST, PZT etc.), and/or conductors (e.g., Pt, Ru, Ir, Cu etc.). The use of such an annealing procedure enables a thermal ramp rate to be controlled at a substantially fast rate, such that the bulk of the substrate lags significantly behind a targeted upper layer. In other words, the annealing process of the present invention enables a targeted thin film or layer on the substrate to be heated and cooled in a fraction of a second (i.e., often microseconds or milliseconds), while the underlying layers remain well below their damage threshold, as heat from the upper layer may be conducted thereaway through the lower layers or radiated away and absorbed by, for instance, a black body environment or similar heat sink. As such, a substrate with, for example, a 750° C. front or upper surface temperature may be created, while its back side could remain, for example, at 400° C. or below.

To accomplish this, the RTA process of the present invention permits a gradient to be maintained in order to anneal the targeted upper layer, while preserving layers located under the targeted layer. In particular, the annealing process of the present invention employs a series of pulses or flashes (e.g., nanoseconds, microseconds or milliseconds in length of time) to allow for the creation of a temperature gradient within the substrate from targeted layer down in order to extend a reaction time on a targeted layer. In employing a series of pulses or flashes, a single intense flash of energy may be allowed to dissipate before another is initiated. In one embodiment, the time necessary to dissipate a single flash may only be on the order of tens of milliseconds or less. Moreover, since annealing of the targeted layer, such as SBT and other metal oxides, may be reaction limited, and can be finalized upon a cooling cycle, the necessary reaction temperature and energy input can be achieved even while the lower level substrate layers remain cooler due to the heat flux away from the upper hotter surface. Thus, in the above example, a 750° C. treatment of an upper layer for 60 seconds can result in a thermal “budget” for the bulk of the substrate of 24,000 degree C.-sec, since the bulk of the substrate remains at 400° C. for 60 sec. This thermal budget is substantially half of prior art treatments. A more detailed description of the RTA method of the present invention in provided below.

Chemical Fluid Deposition

Thin film layers to be annealed in accordance with an embodiment of the present invention may initially be deposited onto a substrate using various well know approaches, such as Chemical Vapor Deposition, Atomic Layer Deposition, or Sputtering. In accordance with an embodiment of the present invention, a Chemical Fluid Deposition (CFD) process is used to obtain discrete conformal thin films or layers on a substrate.

In general, CFD is a process by which materials (e.g., metals, metal oxides, or organics) may be deposited from a supercritical or near-supercritical solution via chemical reaction of soluble precursors. CFD is generally described in detail in U.S. Pat. No. 5,789,027, which patent is hereby incorporated herein by reference. Desired materials can be deposited on a substrate, such as a silicon wafer, as a high-purity (e.g., better than 99%) thin film (e.g., less than 5 microns). The supercritical fluid employed may be used to transport a precursor material to the substrate surface where a reaction takes place, and to subsequently transport ligand-derived decomposition products away from the substrate to remove potential film impurities. Typically, the precursor in CFD is non-reactive by itself, and a reaction reagent (e.g., a reducing or oxidizing agent) may be mixed into the supercritical solution to initiate the reaction which forms the desired materials. The entire process takes place in solution under supercritical conditions. The process provides a high-purity film at various process temperatures under 250° C., depending on the precursors, solvents, and process pressure used.

Solvents

Solvents that can be used as supercritical fluids are well known in the art and are sometimes referred to as dense gases (Sonntag et al., Introduction to Thermodynamics, Classical and Statistical, 2nd ed., John Wiley & Sons, 1982, p. 40). At temperatures and pressures above certain values for a particular substance (defined as the critical temperature and critical pressure, respectively), saturated liquid and saturated vapor states are identical and the substance is referred to as a supercritical fluid. Solvents that are supercritical fluids are less viscous than liquid solvents by one to two orders of magnitude.

In CFD, the low viscosity of the supercritical solvent facilitates improved transport (relative to liquid solvents) of reagent to, and decomposition products away, from the incipient film. It should be noted that many reagents which would be useful in chemical vapor deposition are insoluble or only slightly soluble in various liquids and gases and thus cannot be used in standard CVD. However, the same reagents often exhibit increased solubility in supercritical solvents. Generally, a supercritical solvent can be composed of a single solvent or a mixture of solvents, including for example, a small amount (<5 mol %) of a polar liquid co-solvent such as methanol.

It is important that the reagents are sufficiently soluble in the super-critical solvent to allow homogeneous transport of the reagents. Solubility in a supercritical solvent is generally proportional to the density of the supercritical solvent. Ideal conditions for CFD include a supercritical solvent density of at least 0.2 g/cm³ or a density that is at least one third of the critical density (the density of the fluid at the critical temperature and critical pressure).

The table below lists some examples of solvents along with their respective critical properties. These solvents can be used by themselves or in conjunction with one another or other solvents to form the supercritical solvent in CFD. The table respectively lists the critical temperature, critical pressure, critical volume, molecular weight, and critical density for each of the solvents.

Critical Properties of Selected Solvents

| | T_{c} | P_{c} | V_{c} | Molecular | ρ_{c} |
|---|---|---|---|---|---|
| Solvent | (K) | (atm) | (cm/mol) | Weight | (g/cm³) |
| CO₂ | 304.2 | 72.8 | 94.0 | 44.01 | 0.47 |
| C₂H₆ | 305.4 | 48.2 | 148 | 30.07 | 0.20 |
| C₃H₈ | 369.8 | 41.9 | 203 | 44.10 | 0.22 |
| n-C₄H₁₀ | 425.2 | 37.5 | 255 | 58.12 | 0.23 |
| n-C₅H₁₂ | 469.6 | 33.3 | 304 | 72.15 | 0.24 |
| CH₃—O—CH₃ | 400 | 53.0 | 178 | 46.07 | 0.26 |
| CH₃CH₂OH | 516.2 | 63.0 | 167 | 46.07 | 0.28 |
| H₂O | 647.3 | 12.8 | 65.0 | 18.02 | 0.33 |
| C₂F₆ | 292.8 | 30.4 | 22.4 | 138.01 | 0.61 |

Carbon dioxide (CO₂) is a particularly good choice of solvent for CFD. Its critical temperature (31.1° C.) is close to ambient temperature and thus allows the use of moderate process temperatures (<80° C.). It is also unreactive with most precursors used in CVD and is an ideal media for running reactions between gases and soluble liquids or solid substrates. Other suitable solvents include, for example, ethane or propane, which may be more suitable than CO₂ in certain situations, e.g., when using precursors which can react with CO₂, such as complexes of low-valent metals containing strong electron-donating ligands (e.g., phospines).

Precursors and Reaction Mechanisms

Precursors may be chosen so that they yield the desired material on the substrate surface following reaction with the reaction reagent. Materials can include metals (e.g., Cu, Pt, Pd, and Ti), elemental semiconductors (e.g., Si, Ge, and C), compound semiconductors (e.g., III-V semiconductors such as GaAs and InP, II-VI semiconductors such as CdS, and IV-VI semiconductors such as PbS), oxides (e.g., SiO₂ and TiO₂), or mixed metal or mixed metal oxides (e.g., a superconducting mixture such as Y—Ba—Cu—O). Organometallic compounds and metallo-organic complexes are an important source of metal-containing reagents and are particularly useful as precursors for CFD. In contrast, most inorganic metal-containing salts are ionic and relatively insoluble, even in supercritical fluids that include polar modifiers such as methanol.

Some examples of useful precursors for CFD include metallo-organic complexes containing the following classes of ligands: beta-diketonates (e.g., Cu(hfac)₂ or Pd(hfac)₂, where hfac is an abbreviation for 1,1,1,5,5,5-hexafluoroacetylacetonate), alkyls (e.g., Zn(ethyl)₂ or dimethylcyclooctadiene platinum (CODPtMe₂)), allyls (e.g. bis(allyl)zinc or W(π⁴-allyl)4), dienes (e.g., CODPtMe₂), or metallocenes (e.g., Ti(π⁵-C₅H₅)₂ or Ni(π⁵-C₅H₅)₂). For a list of additional potential precursors see, for example, M. J. Hampden-Smith and T. T. Kodas, Chem. Vap. Deposition, 1:8 (1995).

It should be noted that precursor selection for CVD is limited to stable organometallic compounds that exhibit high vapor pressure at temperatures below their thermal decomposition temperature. This limits the number of potential precursors. On the other hand, CFD obviates the requirement of precursor volatility, and instead replaces it with a much less demanding requirement of precursor solubility in a supercritical fluid.

Any reaction yielding the desired material from the precursor can be used in CFD. However, low process temperatures (e.g., less than 250° C., 200° C., 150° C., or 100° C.) and relatively high fluid densities (e.g., greater than 0.2 g/cm³) in the vicinity of the substrate are important features of CFD. If the substrate temperature is too high, the density of the fluid in the vicinity of the substrate approaches the density of a gas, and the benefits of the solution-based process may be lost. In addition, a high substrate temperature can promote deleterious fragmentation and other side-reactions that lead to film contamination. Therefore a reaction reagent, rather than thermal activation, may be used in CFD to initiate the reaction that yields the desired material from the precursor.

For example, the reaction can involve reduction of the precursor (e.g., by using H₂ or H₂S as a reducing agent), oxidation of the precursor (e.g., by using O₂ or N₂O as an oxidizing agent), or hydrolysis of the precursor (i.e., adding H₂O). An example of an oxidation reaction in CFD is the use of O₂ (the reaction reagent) to oxidize a zirconium beta-diketonate (the precursor) to produce a metal thin film of ZrO₂. An example of a hydrolysis reaction in CFD is water (the reaction reagent) reacting with a metal alkoxide (the precursor), such as titanium tetraisopropoxide (TTIP), to produce a metal oxide thin film, such as TiO₂. The reaction can also be initiated by optical radiation (e.g., photolysis by ultraviolet light). In this case, photons from the optical radiation can be the reaction reagent.

In this supercritical processing approach, chemical selectivity at the substrate can be enhanced by a temperature gradient established between the substrate and the supercritical solution. For example, a gradient of 40° C. to 250° C. or 80° C. to 150° C. can be beneficial. However, to maintain the benefits of CFD, the temperature of the substrate measured in Kelvin, divided by the average temperature of the supercritical solution measured in Kelvin, may typically be maintained between 0.8 and 1.7.

In some cases, the supercritical fluid can participate in the reaction. For example, in a supercritical solution including N₂O as a solvent and metal precursors such as organometallic compounds, N₂O can serve as an oxidizing agent for the metal precursors yielding metal oxides as the desired material. In most cases, however, the solvent in the supercritical fluid is chemically inert.

System for Deposition

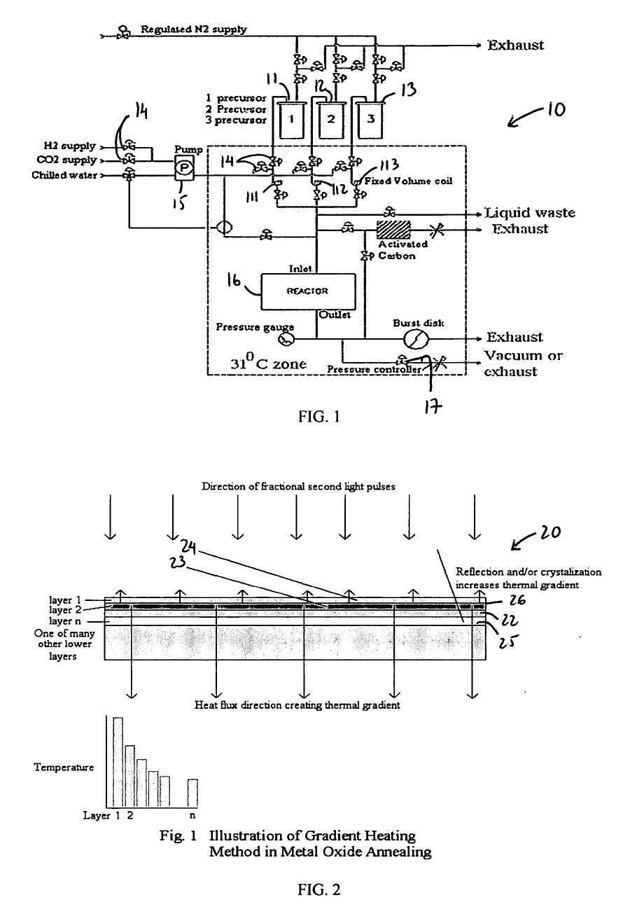

Looking now at FIG. 1, there is illustrated, in accordance with one embodiment of the present invention, a system 10 for implementing a CFD deposition protocol, for example, a hydrogen assisted supercritical deposition protocol. As shown in FIG. 1, vessels 11, 12, and 13 may each be provided with a distinct precursor for subsequent deposition of an individual discrete film layer onto a substrate, such as a silicon substrate situated in a reactor 16. These precursors, examples of which are provided above, may be provided in liquid form and may, in an embodiment, be slightly pressurized by, for instance, N₂ gas. Since the deposition process employed by the present invention involves the use of supercritical gases, such as CO₂, high pressure valves 14 which can withstand the pressures of supercritical gases may be used throughout the system 10.

To initiate the deposition process, a micro-volume of a precursor, such as that from vessel 11, may be generated within a coil of small tubing 111. It should be appreciated that a micro-volume each of the precursors from each of vessels 12 and 13 may also be generated within coils 112 and 113 respectively for sequential deposition of subsequent thin film layers on the substrate.

Next, to generate the supercritical gas, a solvent, such as CO₂, may be supplied to a pump 15 in either liquid form, or as a high-pressure gas. In the case the solvent is to be supplied as a gas, the solvent may subsequently be condensed to a liquid. The liquid solvent may next be pressurized to supercritical pressure, for CO₂ it is about 1100 PSI and can be higher. It should be noted that whether the solvent is supplied as a gas or a liquid, a reaction agent such as Hydrogen (e.g., H₂ gas) may be introduced on the low-pressure or high-pressure side of the pump 15 and allowed to mix with the solvent to assist in the supercritical processing of the precursor for subsequent deposition. Once reaching pressure for supercritical gas conditions, heat may be added to bring this gas mixture up to supercritical temperature. In the case of supercritical CO₂, the temperature is about 31° C.

Upon reaching supercritical pressure and temperature, the supercritical gases (e.g., CO₂ and H₂) may be flushed through the coil 111 containing the respective micro-volumes to substantially dissolve the precursor material. The supercritical gas and precursor mixture may be then directed toward a reactor 16, which may contain or be partially filled with a supercritical gas, such as CO₂. It should be appreciated that the system 10, in one embodiment, may be conditioned to the temperature of the supercritical gas, so as to minimize shock and preserve the supercritical condition for the process. In this example, since about 1100 PSI is employed in connection with CO₂, the system 10 may be maintained at about 31° C. to preserve the supercritical condition. The system 10, in an embodiment, may also be provided with, for instance, pressure gauges and metal burst discs to monitor and maintain the safety of the system 10.

Once the supercritical gas and precursor mixture has been introduced and stabilized within the reactor 16, the temperature of a platform upon which the substrate sits within the reactor 16 may be brought up to that similar to the processing temperature. In the case of SCCO₂ and, for instance, a Platinum precursor, the platform may be heated to about 60° C. It should be appreciated that since, for example, Hydrogen assisted SCCO₂ deposition rates may be zero order dependent on concentration, the temperature may be used as a primary control for the deposition rate. To the extent that other precursors may be used, the temperature of the platform may be varied accordingly up to about 200° C.

After the deposition reaches a desired thickness on the substrate, a high pressure valve 17 downstream of the reactor 16 may be opened, so that substantially all the gases (e.g., SCCO₂, H₂) and solutes (e.g., precursor ligands, unused precursor) can leave the system 10. To facilitate removal of the gases and solutes from the reactor 16 and the precursor paths, additional amounts of SCCO₂ may be used to flush the system 10 since there is substantially good solubility with the gases and the solutes. In one embodiment, a cleaning additive may be used with SCCO₂ to enhance the flushing and cleaning process. A by-product trap, such as an activated carbon canister, may also be provided for use in connection with the cleaning process.

Once the first layer has been deposited onto the surface of the substrate, subsequent thin film layers may be sequentially deposited atop the first layer on the substrate by repeating the steps disclosed above using, for instance, the precursors from vessel 112 and 113 respectively.

Once the deposition process has completed, reactor 16 may be allowed to depressurize toward a transfer pressure. The transfer pressure may be positive or negative (vacuum) depending on the situation. Transfer pressure, in one embodiment, can be achieved through the use of a downstream pressure controller 17 or the use of a connected vent line to the handler (not shown).

Capacitor Fabrication

As noted above, to continue at the present pace of miniaturization of the capacitor, the present invention can provide, in one embodiment, a capacitor having a high k dielectric along with associated metal electrodes and contacts on a high aspect ratio substrate or three dimensional (3-D) cell structure. Such a capacitor may be fabricated, in an embodiment, by employing the system 10 described above using Hydrogen assisted supercritical CO₂ deposition of metal film layers in a reducing environment from precursors, such as metallo-organic precursors. In particular, the system 10 and the supercritical CO₂ deposition process can generate, in an embodiment, conformal film growth on the substrate, either two or three dimensional, at a relatively high speed, while minimizing the occurrence of oxidation of precursors into CO₂, CO etc. to produce substantially pure metal film layers without carbonation or oxide interfaces.

Referring now to FIG. 2, a capacitor 20 may be fabricated in accordance with an embodiment of the present invention. Initially, a substrate 21, such as a doped Silicon substrate, may be provided. Next, a first thin metal film 22 may be conformally deposited onto the surface of substrate 21, using Hydrogen assisted SCCO₂ deposition of a precursor, such as a metallo-organic precursor or one of the precursors disclosed above, in a reducing environment. This thin metal film 22 may thereafter be oxidized in 02 at a temperature ranging from about 300° C. to about 600° C. depending on the precursor used to form a dielectric layer. In one embodiment, this thin metal layer 22 (i.e., the dielectric layer) can be a high k dielectric if the precursor used includes, for instance, SrTa, Hf, Ta, Al, or HfSi. Of course, other related metals or metal alloys, such as Pb, Zr, Ti, BiLaTi, SrTaNiNb, SrTaBi, BiTi, PbZrTi or SrTi, or a combination thereof may be used. It should be noted that the annealing process can provide the dielectric layer 22 with adhesive characteristics, compatible grain size, and compatible thermal expansion to that of subsequent layers.

In providing capacitor 20 with high aspect ratio to achieve relatively high capacitance, the total thickness of the metal film layers thereon, in an embodiment, may range from about 50 Angstroms to about 5000 Angstroms or more on the substrate 21. In an embodiment, the first or starting thin layer 22 on the surface of substrate 21 may be provided with a thickness ranging from about 10 Angstroms to about 1000 Angstroms. Subsequent layers may also be provided with a similar or different thickness range, depending on the materials. For instance, the thickness range may be from about 50 to about 500 Angstroms for dielectrics, and from about 500 to about 5000 Angstroms for metal electrodes. It should be noted that in the Hydrogen assisted SCCO₂ process employed herein, the desired thickness for the first thin layer 22 can be achieved relatively quickly, for instance, in about a minute or less.

After the first thin metal layer 22 (i.e., dielectric layer) has been formed, a second thin metal film 23 can be deposited atop the first thin metal layer 22 using a precursor metal, or one whose oxide is conductive, examples of which include, Ru, Ir, Pt, Al, Ag, Au, Pd, Cu, AlCu, AlCuSi, etc., to complete the formed capacitor 20. The second thin metal film 23 may subsequently be oxidized in O₂ at a temperature ranging from about 300° C. to about 600° C. depending on the precursor used to form a top electrode layer. In the case of Ru and Ir for instance, the oxidation process can provide the top electrode layer 23 with a conductive oxide which can also act as a gas barrier. The oxidation process can also provide the top electrode layer 23 with adhesion characteristics, compatible or desired grain size, and compatible thermal expansion, among others, similar to that of the dielectric layer 22.

It should be noted that if electrode layer 23 is composed of a noble metal, then no oxidation takes place, but the layer can permit oxygen to permeate therethrough to oxidize the other layers.

In an alternate embodiment, the first thin metal film 22 and the second thin metal film 23 can initially be deposited in sequence. Thereafter, a single oxidation step in O₂, can be performed to simultaneously oxidize the first thin metal film to form the dielectric layer 22 and the second thin metal film to form the conductive top electrode 23. Although described in connection with the Hydrogen assisted SCCO₂ deposition process, it should be noted that the deposition of the film for the top electrode layer 54 may be carried out with or without the Hydrogen assisted SCCO₂ deposition process.

In another embodiment, a barrier layer 24 may be deposited atop the top electrode layer 23 to protect against oxide reduction, for instance, due to subsequent interconnect processing. In particular, a precursor metal or alloy, or one whose oxide can act as a barrier to a gas (e.g., Hydrogen or Oxygen), or a barrier to a semiconductor contaminant element, such as Na, Ca, or Ru, may be used to form a third thin film on the top electrode layer 54. Examples of such metal, alloy or oxides thereof include Ru, Ir, Al, Cu, Pd, Au, Ag, Pt or a combination thereof. Once deposited, this third thin metal film may subsequently be oxidized in O₂ at a temperature ranging from about 300° C. to about 600° C., depending on the precursor used, to form the barrier layer 24. The oxidation process can also provide the barrier layer 24 with adhesion characteristics, compatible grain size, and compatible thermal expansion to that of the other layers. Moreover, although described in connection with the Hydrogen assisted SCCO₂ deposition process, it should be noted that the deposition of the barrier layer 24 may be carried out with or without the Hydrogen assisted SCCO₂ deposition process. Furthermore, although not discussed, it should be noted that the barrier layer 24 is deposited only after patterning has taken place on the electrode layer 23.

To the extent desired, a bottom electrode layer 25 may be deposited on to the surface of substrate 21 prior to deposition of the film for the dielectric layer 22. Deposition of a thin metal film for the bottom electrode layer 25, in one embodiment, may be implemented in a similar manner, using similar choices for a precursor material, and oxidized in substantially the same way as that carried out with the top electrode layer 23. In addition, a barrier layer may be deposited onto the lower electrode layer 25 prior to deposition of the dielectric layer 22. In certain instances, it may also be advantageous to utilize a metal oxide adhesion layer, for instance, Titanium oxide, to enhance adhesion of the lower metal electrode to the substrate 21.

In providing a bottom electrode layer 25, the dielectric layer 22, as shown in FIG. 2, may be sandwiched between the top electrode layer 23 and the bottom electrode layer 25. In such an embodiment, substrate 21 may need not be electrically conductive, as the bottom electrode layer 25 and the top electrode layer 23 can provide the necessary conductive loop (i.e., circuit) for the capacitor 20. Moreover, the substrate 21 may be dielectric, such as SiO₂, to minimize unwanted capacitance underneath the lower electrode layer 25.

Rapid Thermal Annealing

Once the thin films or layers have been deposited, a rapid a thermal annealing (RTA) process, in accordance with one embodiment of the present invention, may be employed to strengthen and reduce brittleness of a targeted layer(s).

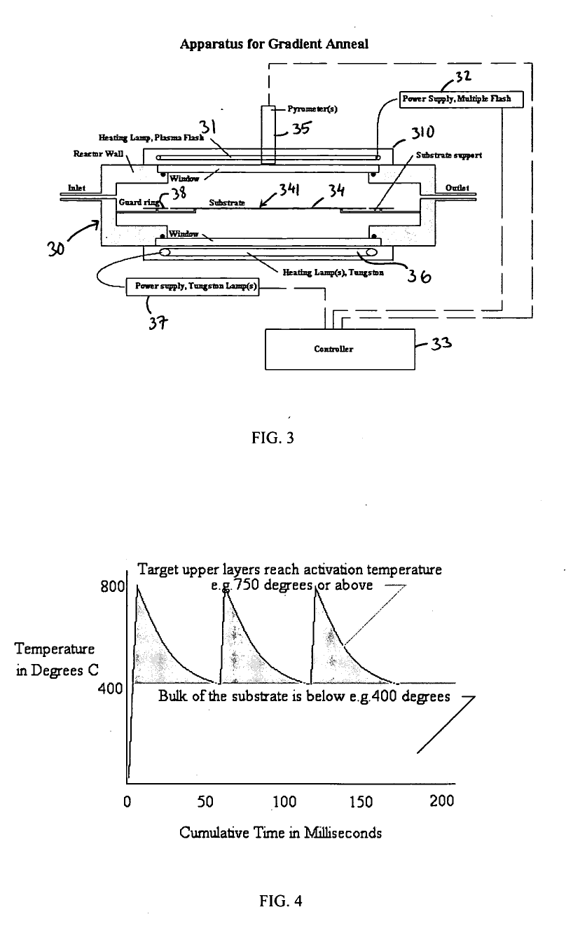

To implement the RTA method of the present invention, a reactor 30, as illustrated in FIG. 3, may be provided for use in connection with system 10 to permit a series of rapid pulses or flashes of heat energy. In one embodiment, reactor 30 includes a heat source 31, such as a laser, a flash lamp, a microwave pulse generator, a fast responding argon plasma arc lamp, or other similar sources for emitting a series of rapid pulses or flashes of heat energy. In accordance with one embodiment of the present invention, heat source 31 may be an argon plasma arc lamp, similar to a replaceable flash bulb lamp manufactured by ILC Technology of Sunnyvale, Calif., and may be powered, in an embodiment, by a power supply 32 capable of providing high current pulses of electric energy, similar to a system having model number PS5010 manufactured by EKSMA Company of Vilnius, Lithuania.

The power supply 32, as shown in FIG. 3, may be designed to provide a series of electrical signals capable of activating heat source 31 to emit a flash or pulse of heat energy. In order to do this, instead of the usual one charge storage device (i.e., current capacitor), which can take some time to charge, the power supply 32 may be equipped with a plurality (i.e., at least two) charge storage devices (not shown). In an embodiment, these devices can be programmed to direct, in a time dependent manner, a charge toward the heat source 31 in substantially fast succession, for instance, microseconds or milliseconds apart. Accordingly, by providing a plurality of charge storage devices within the power supply 32, each storage device can be charged up, and discharged toward the heat source 31 in rapid succession. It should be noted that the recharge time of each storage device can determine the number of storage devices required for a particular application. For example, to anneal a metal oxide, such as SBT, several seconds may be required to facilitate the correct crystal orientation and other properties of the material. Thus, if the recharge time of the storage device is 10 seconds, for example, then about ten charge storage devices may be needed to feed 10 seconds worth of one second interval flashes. Ten storage devices can therefore sustain a series of flash repetitions without the need for a pause.

In an embodiment, the power of each flash of energy from heat source 31 can be in the range of about 4.0 MW to about 6.0 MW, and may have a duration in the range of up to 6 milliseconds. Of course, the duration can be nanoseconds, microseconds, or milliseconds in length or less depending on the material being annealed. The selection of the duration and power level of the flash of heat energy, in one embodiment, can be selected by system controller 33.

Still referring to FIG. 3, heat source 31 may be situated within housing 310 positioned on an upper side of reactor 30, and may direct emitted pulses of heat energy through opening 311 toward substrate 34 in reactor 30. In order to substantially uniformly direct heat energy from heat source 31 toward an upper surface 341 of substrate 34, housing 310 may be coated with a reflective material, for instance, polished gold or polished aluminum. Alternatively or in addition, housing 310 may be shaped in such a manner so as to substantially uniformly reflect heat energy toward substrate 34. In another embodiment, housing 310 may be fitted with a plurality of reflectors (e.g., mirrors) capable of reflecting the heat energy toward substrate 34.

Reactor 30 may also include heat sensor, such as a pyrometer 35, designed to measure the temperature of the targeted layer, i.e., the upper surface 341 of substrate 34, between flashes while the heat source 31 is not activated. Measurement between flashes may be employed to avoid interference from broad spectrum flashes. The temperature information obtained by pyrometer 35 may be used to provide a feedback signal to controller 33 in the selection of the duration, power level, and initiation of the next successive flash of heat energy in connection with the annealing process. It should be appreciated that pyrometer 35 may be designed to work in conjunction with or independently of the program controlling the time-dependent emission of a pulse of heat, in the event the duration between pulses, based on the timing program, may be longer than that desired. Alternatively, pyrometer 35 may be inactivated and the emission of the pulses be dependent solely on the timing program, or pyrometer 35 may be fully activated and the timing program inactivated in the control of the pulses. Pyrometer 35, as illustrated in FIG. 3, may be situated adjacent heat source 31. However, it should be noted that pyrometer 35 may be situated anywhere on the reactor 30, so long as pyrometer 35 can measure the appropriate temperature emitted from surface 341 of substrate 34. In one embodiment, pyrometer 35 may be a 1.2 micron wavelength pyrometer for measuring substrate temperature at, above, or below 500° C. Of course other shorter or longer wavelength pyrometers may be used, depending on the application and the substrate temperature being measured. For instance, to measure substrate temperature at around 400° C., a longer wavelength, e.g., up to 8 microns, pyrometer can be used.

Reactor 30 further includes, in one embodiment, a second heat source 36, such as a tungsten lamp, situated adjacent window 361 located along a lower side of reactor 30. The placement of the second heat source 36 along window 361 may be used to direct a steady stream of heat from heat source 36 toward a backside 342 of substrate 34. By doing so, the temperature throughout substrate 34 may be raised to a substantially uniform intermediate temperature prior to exposing the upper surface 341 to a series of pulses or flashes of heat energy from heat source 31. Raising the substrate to an intermediate temperature can prevent extreme thermal gradient between the targeted layer and the underlying layer. As a result, strains to the underlying layers can be reduced, thus minimizing damage to these layers. In one embodiment, pyrometer 35 may be used to measure the temperature of substrate 34 prior to activating heat source 31, so that a series of heat energy pulses or flashes may be emitted toward the targeted upper surface 341. The second heat source 36, as shown in FIG. 3, may be powered by power supply 37 designed to be controlled by system controller 33. However, since a series of rapid pulses of heat energy may not be needed from the second heat source 36, power supply 37, unlike power supply 32, may not need a plurality of charge storage devices.

In operation, after the layers have been deposited onto substrate 34, substrate 34 may be pre-heated to an intermediate temperature, for instance below about 400° C. (see FIG. 4), by the second heat source 36, such as a tungsten lamp. Once the intermediate temperature, which can range between about 200° C. and about 400° C. has been reached, feedback signals may be generated by pyrometer 35 from appropriate wavelength (e.g. above 1.2 micron for below 500 degrees, and 1.2 or below for above 500 degrees Centigrade). Thereafter, while substrate 34 may be maintained at the intermediate temperature, and based on the feedback signals from pyrometer 35, a flash or pulse of heat energy may be emitted from heat source 31 toward upper surface 341, i.e., a targeted layer, such as the first or upper layer 22 in FIG. 2. In one embodiment, the initial flash or pulse may be emitted at a first temperature range higher than the intermediate temperature and sufficient to anneal the targeted layer, for instance, about 800° C. (see FIG. 4), but can be between about 400° C. and about 1000° C. depending on the material. However, this initial flash or pulse has a duration which may last only for a predetermined period of time, for instance, nano-, micro-, or milli-seconds in length, and less than that necessary to render the targeted layer on substrate 34 substantially annealed. In this manner, exposure of non-targeted layers to the flash or pulse of high heat energy can be minimized. Specifically, since the temperature of the flash or pulse is relatively high, prolonged exposure of the non-targeted layers to the flash or pulse at the first temperature range can impart damage to the crystalline structures within these layers.

Next, the targeted layer may be permitted to cool to a second temperature range that is between the first temperature range and the intermediate temperature, for instance, about 400° C. but can be between about 300° C. and about 600° C. depending on the material, so as to avoid termination of the annealing process. The cooling period, in accordance with an embodiment of the present invention, can be relatively quick. In particular, since the thermal mass of the substrate can be significant compared to that of the targeted layer, and since the duration of the flash at the first temperature range may be relatively short, the underlying layers (i.e., bulk of the substrate) may act to quickly conduct heat away from the targeted layer. In addition, the walls of reactor 30 may act as a heat sink, similar to a black body, to absorb heat reflected and thermally emitted by the substrate.

Upon reaching the second temperature range, in one embodiment, feedback signals from pyrometer 35 can act to re-activate heat source 31 to emit another flash or pulse of heat energy at the first temperature range, for example, about 800° C. Alternatively, in the event the pyrometer 35 is inactivated, a timing program may act to control, between each pulse of heat energy, a duration sufficient to permit cooling of the targeted layer to a second temperature range below the first temperature range prior to the initiation of the next successive pulse of heat energy. To that end, the targeted layer may again be exposed to the first temperature range for substantially the same predetermined period of time as the initial pulse to incrementally raise the temperature of the targeted layer, while maintaining minimal exposure of the remaining layers to the first temperature range.

The targeted layer may continue to be cooled and re-exposed to a series of flashes or pulses of heat energy from heat source 31 until the temperature of the targeted layer reaches the desired annealing temperature, for instance, about 800° C., and the targeted layer is substantially annealed. In particular, the implementation of a series of flashes or pulses of heat energy can incrementally raise the temperature of the targeted layer toward the annealing temperature upon each successive pulse or flash as heat energy from each pulse or flash gets absorbed into the targeted layer. Moreover, due to the shortness of the duration of pulses or flashes, exposure of the remaining layers to the high heat from the pulses or flashes can be minimized to avoid damages those layers.

It should be noted that the walls of the reactor 30 and other components within reactor 30 may act to conduct or pull heat away from the targeted layer of substrate 34 during the annealing process, such that the temperature of the targeted layer may fall below a desired level. Accordingly, a heat retaining component, such as ring 38, may be positioned about the substrate 34, so as to minimize the conduction of heat away from the targeted layer. In particular, upon emission of the pulse or flash of heat energy from heat source 31, the targeted layer along with the ring 38 may be heated to substantially the same temperature. Thus, the proximity of the heated ring 38 to the similarly heated targeted layer of substrate 34 can act to minimize the conduction of heat therefrom. Of course, ring 38 need not be utilized should the heat sink effect caused by the walls and components within reactor 30 can be minimized.

To further confine heat to the targeted layer, looking again at FIG. 2, a reflective layer 26 may be deposited onto layer 22 prior to the deposition of the targeted layer 24. The use of a reflective layer, such as Ru, Pt, and Ir can help to reflect radiation from the emitted heat energy back to the targeted layer, thereby maintaining the desired higher temperature within the targeted layer.

It should be noted that the flash or pulse power, duration, interval, and the number of pulses, in one embodiment, may differ from the levels provided above and may be varied until the temperature of the targeted layer has reached the desired first temperature range for annealing. Moreover, by employing a series of flashes or pulses to heat a targeted layer to a higher temperature than the bulk of the substrate, a substantially steady gradient of temperature can be approximated from the targeted layer down to the bulk of the substrate (see graph in FIG. 2).

As an example, a desired result for an application such as SBT may be to expose the upper layer of the platinum electrode and/or the SBT layer to approximately 700° C. for several seconds cumulatively, while the bulk of the substrate, including the remaining underlying layers, may remain at or below 500° C., i.e., the intermediate temperature, to protect implanted levels in the underlying layers from diffusing, as well as any interconnects from oxidizing. Moreover, the ratio of temperature in the upper layer to that of the lower layers can be selected in order to prevent excess thermal stress, which can lead to breakage of the substrate. Typically, the temperature ratio may be about 1.3 to 1.

For applications such as BST, anneal temperatures may be as low as 400° C. Therefore the intermediate temperature can be set to, for instance, 300° C. degrees, while the upper layer can be cumulatively heated to 400° C. with the series of flashes. To measure the substrate at these lower temperature, longer wavelength pyrometers may be used (e.g. up to 8 microns) to avoid regions of ambiguity at the shorter wavelengths in, for example, Silicon substrates. Other well known optical sampling methods can be used (e.g. fiber optic sampling, stimulation and re-emission methods, and guard ring telltale instrumentation.) As noted previously, the sampling of the pyrometer voltage output may be done between flashes to avoid interference from the broad spectrum flash. Otherwise, the use of light stops etc. may be used to isolate the pyrometers view of the substrate.

Although the RTA process is described as being subsequent to the oxidation step, it should be appreciated that the RTA process may be performed prior to the oxidation step or simultaneously with the oxidation step. Moreover, the targeted layer may not necessarily be the uppermost layer. The targeted layer may be any layer deposited on the substrate 34 and can be multiple layers.

The resulting capacitor structure for integrated circuits (Decoupling, Tuning, DRAM, ROM, SRAM, FeRAM etc.) may, in one embodiment, include conformally deposited thin layers, including a high k dielectric layer, that are substantially pure in content. Each thin film layer, in an embodiment, can be provided with about 2% to about 5% thickness uniformity and substantially without an appreciable amount of Carbon.

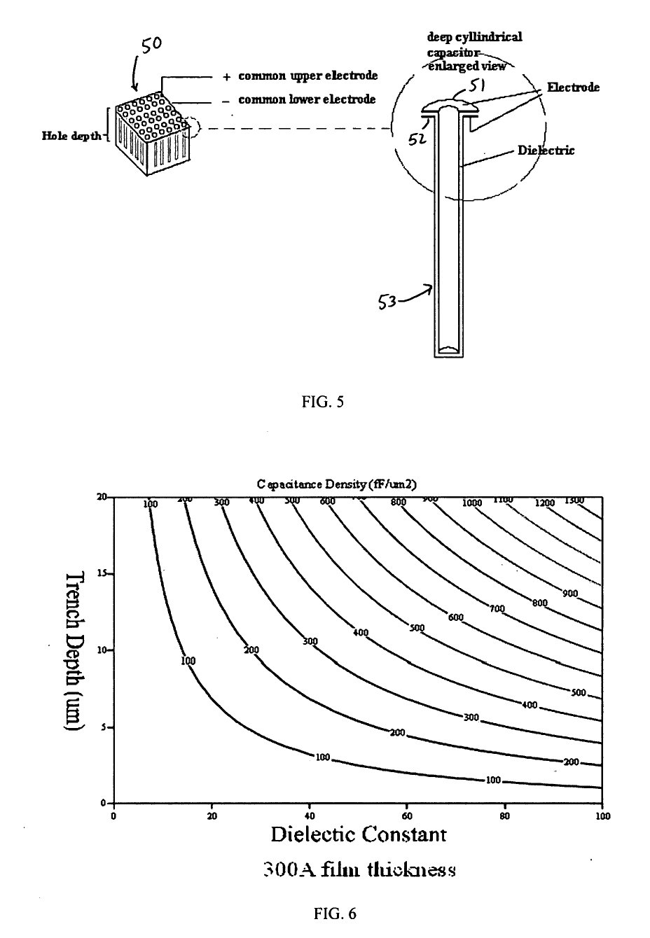

Although shown as a two dimensional capacitor 20, it should be appreciated that a 3 -D capacitor or capacitor array, such as capacitor array 50 shown in FIG. 5, may be fabricated in connection with the Hydrogen assisted SCCO₂ deposition process employed by the present invention. The array 50, in one embodiment, may be provided with a common top electrode 51 and a common bottom electrode 52 rather than individual top and bottom electrodes for each capacitor 53 in the array 50. With such a 3-D array, capacitor 50 can exhibit, in one embodiment, an increase in capacitance density up to about 1500 times (see FIG. 6). Alternatively, capacitor array 50 may be made approximately 150 times smaller than current high k designs, while maintaining similar capacitance density to that of current designs. Such characteristics can easily provide a solution to IC chip isolation problem and enable implementation of higher-speed logic, microprocessor, mobile and memory LSI circuits, among others.

The resulting capacitor structure for integrated circuits (Decoupling, Tuning, DRAM, ROM, SRAM, FeRAM etc.) may, in one embodiment, be provided with high aspect ratio feature over 5:1, e.g., ranging from at about 5:1 to about 100:1 depth to width, and may include conformally deposited thin layers, including a high k dielectric layer, that are substantially pure in content.

The foregoing has outlined, in general, certain aspect of the invention and is to serve as an aid to better understanding the more complete detailed description which is to follow. In reference to such, there is to be a clear understanding that the present invention is not limited to the method or detail of construction, fabrication, material, or application of use described and illustrated herein. Any other variation of fabrication, use, or application should be considered apparent as an alternative embodiment of the present invention.

What is claimed is:

1. A method for annealing layers on a substrate, the method comprising:
providing, on a substrate, a plurality of overlapping thin film layers;
generating a first temperature range sufficient to anneal a targeted layer on the substrate;
exposing the targeted layer to the first temperature range for a predetermined time period less than that necessary to render the targeted layer substantially annealed, so as to minimize exposure of the remaining layers to the first temperature range;
cooling the targeted layer to a second temperature range below the first temperature range; and
re-exposing the targeted layer to the first temperature range over the predetermined time period to raise the temperature of targeted layer from the second temperature range towards the first temperature range, while allowing minimal exposure of the remaining layers to the first temperature range.

2. A method as set forth in claim 1, wherein, in the step of providing, the overlapping layers include one of a metal material, metal alloy, metal oxide or a combination thereof.

3. A method as set forth in claim 2, wherein, in the step of providing, the layers including the metal material or metal alloy include one of Pt, Ru, Ir, Au, Ag, Al, Pr, Pd, Cu or a combination thereof.

4. A method as set forth in claim 2, wherein, in the step of providing, the layers including the metal oxide include on of O, Cl, F, N, Br, I, Hf, Al, Ru, Ir, Ti, Ta, Bi, Pb, Zr, Sr, SrTa, SrTi, BiTi, BiSrTa, BiLaTi, PbZrTi, SrTaNiNb, or a combination thereof.

5. A method as set forth in claim 1, wherein the step of providing includes depositing a reflective layer under the targeted layer, so as to reflect heat energy back to the targeted layer.

6. A method as set forth in claim 1, wherein, in the step of generating, the first temperature range is from about 400° C. to about 1000° C.

7. A method as set forth in claim 1, wherein, in the step of exposing, the predetermined time period includes one of nanoseconds, microseconds or milliseconds in length.

8. A method as set forth in claim 1, wherein the step of exposing includes allowing more than one layer to be targeted for annealing.

9. A method as set forth in claim 1, wherein, in the step of cooling, the second temperature range is from about 300° C. to about 600° C.

10. A method as set forth in claim 1, wherein the step of cooling includes permitting the underlying layers to conduct heat away from the targeted layer.

11. A method as set forth in claim 1, wherein the step of re-exposing includes incrementally raising the temperature of the targeted layer toward the first temperature range.

12. A method as set forth in claim 1, wherein the step of re-exposing includes creating a thermal gradient from the targeted layer to the underlying layers.

13. A method as set forth in claim 1, further including repeating steps of generating, exposing, cooling, and re-heating until the targeted layer is substantially annealed.

14. A method as set forth in claim 1, further including, prior to the step of exposing, heating the plurality of layers on the substrate to an intermediate temperature below the first temperature range and the second temperature range.

15. A method as set forth in claim 14, wherein the step exposing includes maintaining the underlying layers at the intermediate temperature.

16. A method for annealing layers on a substrate, the method comprising:
pre-heating a substrate having a plurality of overlapping thin film layers to an intermediate temperature;
emitting, toward a targeted layer on the substrate, a rapid pulse of heat energy at a first temperature range that is higher than the intermediate temperature and sufficient to anneal a targeted layer on the substrate, but for a predetermined time period less than that necessary to render the targeted layer substantially annealed, so as to minimize exposure of the remaining layers to the first temperature range;
cooling the targeted layer to a second temperature range below the first temperature range but higher than the intermediate temperature; and
directing, toward the targeted layer, another rapid pulse of heat energy at the first temperature range for the duration of the predetermined time period to raise the temperature of targeted layer from the second temperature range towards the first temperature range, while allowing minimal exposure of the remaining layers to the first temperature range.

17. A method as set forth in claim 16, wherein the step preheating includes maintaining the layers on the substrate at the intermediate temperature.

18. A method as set forth in claim 16, wherein the step of directing includes incrementally raising the temperature of the targeted layer toward the first temperature range.

19. A method as set forth in claim 16, wherein the step of directing includes creating a thermal gradient from the targeted layer to the underlying layers.

20. A method as set forth in claim 1, further including repeating steps of generating, exposing, cooling, and re-heating until the targeted layer is substantially annealed.

21. A reactor for performing rapid thermal annealing, the reactor comprising:
a platform upon which a substrate having a plurality of layers to be annealed can be positioned;
a heat source for emitting toward a targeted layer on the substrate a series of rapid pulses of heat energy, each individual pulse being at a first temperature range and lasting for a predetermined time period less than that necessary to render the targeted layer substantially annealed, and in succession capable of incrementally raising the targeted layer to a temperature sufficient for annealing, while minimizing exposure of the remaining layers to the pulses of heat energy; and
a sensor to measure, upon cooling of the targeted layer between pulses, a second temperature range of the targeted layer below the first temperature range to provide a feedback signal used in the initiation of the next successive pulse of heat energy.

22. A reactor as set forth in claim 21, wherein the heat source is one of a laser, a flash lamp, a microwave pulse generator, a fast responding argon plasma arc lamp.

23. A reactor as set forth in claim 21, wherein the first temperature range from the heat source is from about 400° C. to about 1000° C.

24. A reactor as set forth in claim 21, wherein the predetermined time period is one of nanoseconds, microseconds or milliseconds in length.

25. A reactor as set forth in claim 21, wherein the second temperature range is from about 300° C. to about 600° C.

26. A reactor as set forth in claim 21, further including a reflective material adjacent the heat source to substantially uniformly direct heat from the heat source toward the targeted layer.

27. A reactor as set forth in claim 21, further including a second heat source for heating, prior to the emission of heat energy from the first heat source, the substrate and the plurality of layers to an intermediate temperature below the first temperature range and second temperature range.

28. A reactor as set forth in claim 21, further including a heat sink for positioning about the substrate to minimize conduction of heat away from the targeted layer.

29. A reactor for performing rapid thermal annealing, the reactor comprising:
a platform upon which a substrate having a plurality of layers to be annealed can be positioned;
a heat source for emitting toward a targeted thin film layer on a substrate a series of rapid pulses of heat energy, each individual pulse being at a first temperature range and lasting for a predetermined time period less than that necessary to render the targeted layer substantially annealed, and in succession capable of incrementally raising the targeted layer to a temperature sufficient for annealing, while minimizing exposure of non-targeted thin film layers on the substrate to the pulses of heat energy; and
a timing mechanism to control, between each pulse of heat energy, a duration sufficient to permit cooling of the targeted layer to a second temperature range below the first temperature range prior to the initiation of the next successive pulse of heat energy.

30. A reactor as set forth in claim 29, wherein the first temperature range from the heat source is from about 400° C. to about 1000° C.

31. A reactor as set forth in claim 29, wherein the second temperature range is from about 300° C. to about 600° C.

32. A reactor as set forth in claim 29, further including a reflective material adjacent the heat source to substantially uniformly direct heat from the heat source toward the targeted layer.

33. A reactor as set forth in claim 29, further including a second heat source for heating, prior to the emission of heat energy from the first heat source, the substrate, the targeted layer, and the non-targeted thin film layers to an intermediate temperature below the first temperature range and second temperature range.
